(19) United States
(12) Patent Application Publication
(10) Pub. No.: US 2015/0129295 A1
(43) Pub. Date: May 14, 2015

(54) DOUBLE-SHOT INJECTION MOLDING FORMED LED LEAD FRAME STRUCTURE

(71) Applicant: I-CHIUN PRECISION INDUSTRY CO., LTD., New Taipei City (TW)

(72) Inventors: Ting-Hsi LI, New Taipei City (TW); Yu-Jen LIN, New Taipei City (TW)

(73) Assignee: I-CHIUN PRECISION INDUSTRY CO., LTD., New Taipei City (TW)

(21) Appl. No.: 14/076,780

(22) Filed: Nov. 11, 2013

(51) Int. Cl. H01L 33/62

(52) U.S. Cl. CPC H01L 33/62
USPC 174/261

(57) ABSTRACT

A double-shot injection molding formed LED lead frame structure includes an inner base having an inner bottom portion and an inner surrounding wall surrounding on top of the inner bottom portion, the inner surrounding wall forming a central hollow portion on top of the inner bottom portion, and the inner bottom portion having an inner surface facing toward the central hollow portion; a plurality of conductive pins with each one thereof constructed by a soldering section, a securement section and an extension section respectively; and an outer base comprising an outer bottom portion attached to a bottom of the inner bottom portion and an outer surrounding wall surrounding on top of the outer bottom portion and enclosing an outer of the inner surrounding wall; wherein each one of the securement sections of the conductive pins extends to arch between the inner bottom portion and the inner surrounding wall.

### BACKGROUND OF THE INVENTION

1. Field of the Invention

The present invention is related to a light emitting diode (LED), in particular, to a double-shot injection molding formed LED lead frame structure.

2. Description of Related Art

Generally, a traditional LED lead frame is constructed by a non-conductive base enclosing at least two conductive pins; wherein the conductive pins extends outward to the external of the non-conductive base in a straight form at the portion enclosed by the non-conductive base, upon which they are further arched to be as soldering portions. As a result, such structure is prone to water vapor penetration from the external to directly enter into the central receiving space where the LED chip is received therein along the flat contacting portions between the conductive pins and the non-conductive base, which then unfavorably causes the light decay of the LED as well as shortens the useful life of the LED.

In view of the above, after years of research and development as well as application of theories in the field, the inventor of the present invention seeks to overcome the aforementioned shortcoming by providing a novel design in light of improvements thereto.

### SUMMARY OF THE INVENTION

A primary objective of the present invention is to provide a double-shot injection molding formed LED lead frame structure, which utilizes an arched structure of the conducive pins for contacting with the non-conductive base in order to increase its resistance against external water penetration and to prevent unfavorable problems associated with the penetration of external water vapors therein while reducing the improper light decays of the LED and improving its useful life.

Another objective of the present invention is to provide a double-shot injection molding formed LED lead frame structure, which uses double-shot injection molding formed inner and outer bases to enclose the arched structure of the aforementioned conductive pins such that not only the attachment strength between the non-conductive base and the conductive pins is increased but also the difficulties in the water vapor penetration to the inside is further improved in order to enhance the aforementioned effects.

To achieve the aforementioned objectives, the present invention provides a double-shot injection molding formed LED lead frame structure comprising an inner base, a plurality of conductive pins and an outer base; the inner base comprising an inner bottom portion and an inner surrounding wall surrounding on top of the inner bottom portion; the inner surrounding wall forming a central hollow portion on top of the inner bottom portion; and the inner bottom portion having an inner surface facing toward the central hollow portion; the plurality of conductive pins with each one thereof constructed by a soldering section, a securement section and an extension section respectively; and the outer base enclosing an outer of the inner base and the securement sections of the plurality of the conductive pins and comprising an outer bottom portion attached to a bottom of the inner bottom portion and an outer surrounding wall surrounding on top of the outer bottom portion and enclosing an outer of the inner surrounding wall; wherein each one of the soldering sections of the plurality of conductive pins is received within the central hollow portion and is attached to the inner surface; each one of the securement sections of the plurality of conductive pins extends to arch between the inner bottom portion and the inner surrounding wall; and each one of the extension sections of the plurality of conductive pins is connected to the securement section and extends outward to an outer of the outer base.

### BRIEF DESCRIPTION OF DRAWING

FIG. 1 is a cross sectional view of the present invention formed by first-shot injection molding;

FIG. 2 is a cross sectional view of the present invention formed by double-shot injection molding;

FIG. 3 is a cross sectional view of the present invention having the conductive pins being arched;

FIG. 4 is a top view of the present invention shown in FIG. 3; and

FIG. 5 is a cross sectional view of the present invention after being packaged for the formation thereof.

### DETAILED DESCRIPTION OF THE INVENTION

The following provides detailed description of embodiments of the present invention along with the accompanied drawings. It can, however, be understood that the accompanied drawings are provided for illustrative purposes only and shall not be treated as limitations to the present invention.

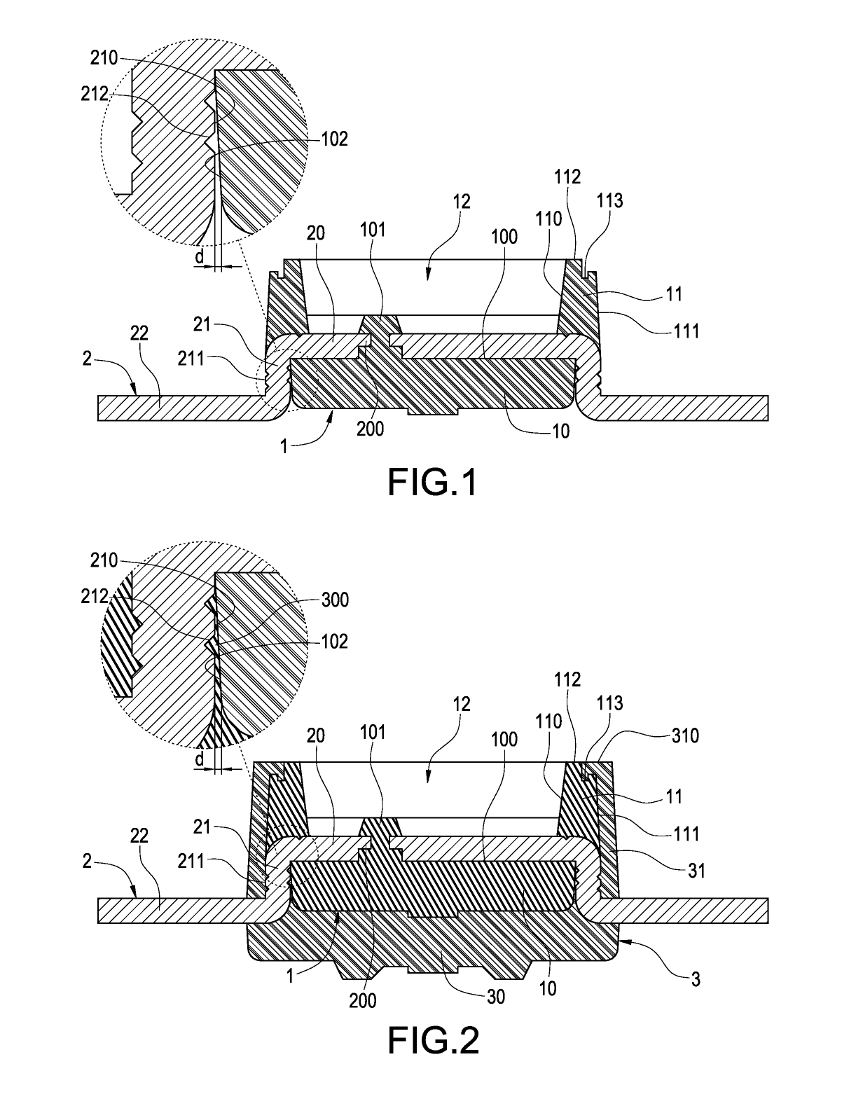

Please refer to FIG. 1 and FIG. 2 showing a cross sectional view of the present invention formed by first-shot injection molding and a cross sectional view of the present invention formed by double-shot injection molding respectively. The present invention provides a double-shot injection molding formed LED lead frame structure comprising an inner base 1, a plurality of conductive pins 2 and an outer base 3.

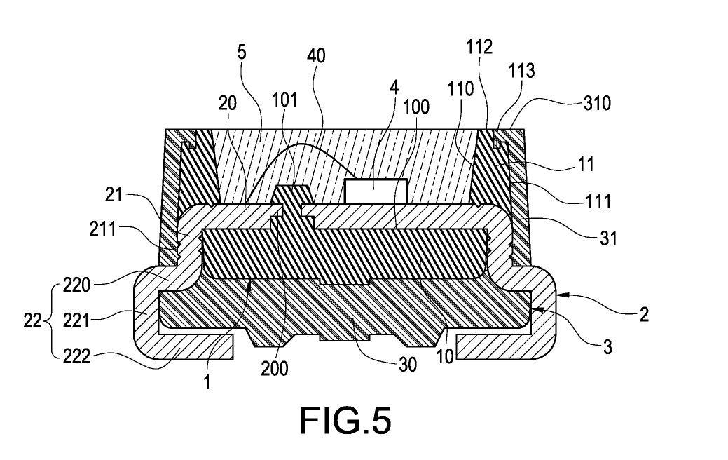

The inner base 1 is made of a non-conductive material and is constructed by an injection molding formation method to enclose the aforementioned conductive pins 2, which comprises an inner bottom portion 10 and an inner surrounding wall 11 surrounding on top of the inner bottom portion 10; the inner surrounding wall 11 surrounds to forms a central hollow portion 12 on top of the inner bottom portion 10 for the LED chip 4 to be received therein and to be electrically connected to the aforementioned conductive pins 2 with a soldering wire 40 (as shown in FIG. 5). In addition, the inner bottom porting 10 includes an inner surface 100 facing toward the central hollow portion 12; the inner surface 100 comprises ribs protruded thereon for the conductive pins 2 to be securely attached thereto; and the inner surrounding wall 11 includes an inner wall surface 110 facing toward the central hollow portion 1 and an outer wall surface 111 opposite from the inner wall surface 110; a top surface 112 is formed at a top portion of the inner surrounding wall 11 and between the inner wall surface 110 and the outer wall surface 111; an indented slot 113 is further formed between the top surface 112 and the outer wall surface 111.

The plurality of conductive pins 2 are arranged on the aforementioned inner base 1 and having each one thereof constructed by a soldering section 20, a securement section 21 and an extension section 22 respectively. Accordingly, wherein the soldering section 20 is received within the central hollow portion 12 of the inner base 1 and is attached to the inner surface 100 of the inner bottom portion 10; a front end of the soldering section 20 is formed of an end edge 200 protruded therefrom for attaching into the ribs 101 of the inner base 1; the securement section 21 extends to arch between the inner bottom portion 10 and the inner surrounding wall 11 and includes an inner edge 210 and an outer edge 211, and a gap d is formed between the inner edge 210 and the inner bottom portion 10 to taper vertically with an increased lower width thereof; the inner and outer edges 210, 211 both includes a insertion pattern 212 formed thereon. Furthermore, the extension section 22 of each one of the plurality of conductive pins 2 is connected to the securement section 21 and extends outward to an outer of the outer base 3.

The outer base 3 is also made of a non-conductive material, which can be of a color darker than that of the inner base 1; for example, the outer base 3 can be constructed by a non-conductive material of a black color whereas the inner base 1 can be constructed by a non-conductive material of a white color. In addition, when the aforementioned inner base 1 is formed by first-shot injection molding to enclose each one of the plurality of conductive pins 2, the outer base 3 can be further formed by double-shot injection molding to enclose the inner base 1 together with the securement section 21 of each one of the plurality of conductive pins 2 such that it comprises an outer bottom portion 30 attached to a bottom of the inner bottom portion 10 and an outer surrounding wall 31 enclosing an outer of the inner surrounding wall 11; wherein the outer surrounding wall 31 is closely attached to the outer wall surface 111 of the inner surrounding wall 11, and a co-plane surface is formed on a top edge of the outer surrounding wall 31 along the top surface 112 of the inner surrounding wall 11 in addition to that a protrusion 310 is further formed to protrude therefrom to insert into the slot in order to construct a single piece altogether.

Furthermore, to allow the outer base 3 to be further attached to the inner base 1 and each one of the plurality of conductive pins 2 firmly, an attachment portion 300 is formed at the aforementioned gap d as the outer bottom portion 30 is formed by injection molding to penetrate therein, which is able to penetrate into the insertion pattern 212 formed on the inner edge 210 of the securement section 21 of each one of the plurality of conductive pins 2; during the same time when the outer surrounding wall 31 is formed by injection molding, it is also able to penetrate into insertion pattern 212 formed on the outer edge 211 of the securement section 21 of each one of the plurality of conductive pins 2 such that the attachment strength among the three is greatly enhanced.

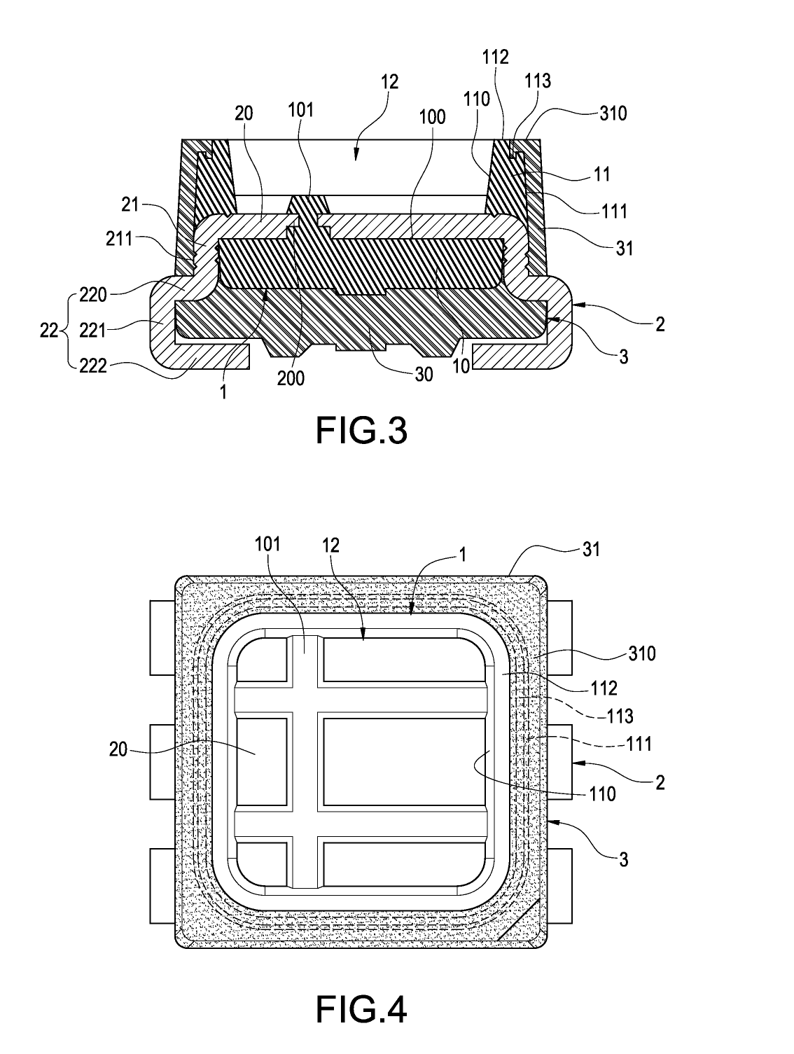

In addition, as shown in FIG. 3 and FIG. 4, the extension section 22 of each one of the plurality of conductive pins 2 can be further arched downward to a C shape in order to form an extended portion 220, a vertical portion 221 and a soldering portion 222; wherein the soldering portion 222 is arched and below the outer bottom portion 30.

Accordingly, as shown in FIG. 5, once being packaged, a package layer 5 is formed inside the central hollow portion 12 of the inner base 1. Since the securement section 21 of each one of the plurality of conductive pins 2 is arranged to extend along and arch between the inner bottom portion 10 and the inner surrounding wall 11 while being enclosed inside the outer base 3, the arched securement section 21 and the enclosed design of the double-shot injection molding formed inner and outer bases 1, 3 are able to increase the difficulty of the water vapor penetration to the inside such that the water penetration resistance is improved to prevent problems associated with the water vapor penetrations and to reduce the improper light decays of LED as well as increase its useful life.

As a result, with the aforementioned structural assembly, the double-shot injection molding formed LED lead frame structure of the present invention can be obtained.

In view of the above, the inventor of the present invention is able to achieve the objectives expected and to overcome the drawbacks of known arts based on great experience and creative concepts, which leads to the utility of the present application to be of novelty and inventive step to comply with the requirements of patentability.

Nevertheless, the above provides preferred embodiments of the present invention for illustrative purposes only, which shall not be treated as limitations of the preset invention; any equivalent changes and modification based on the claims of the present invention shall be deemed to be within the spirit and scope of the present invention as they are further embodiments of the present invention.

What is claimed is:

1. A double-shot injection molding formed LED lead frame structure, comprising:
an inner base comprising an inner bottom portion and an inner surrounding wall surrounding on top of the inner bottom portion, the inner surrounding wall forming a central hollow portion on top of the inner bottom portion, and the inner bottom portion having an inner surface facing toward the central hollow portion;
a plurality of conductive pins with each one thereof constructed by a soldering section, a securement section and an extension section respectively; and
an outer base enclosing an outer of the inner base and the securement sections of the plurality of the conductive pins and comprising an outer bottom portion attached to a bottom of the inner bottom portion and an outer surrounding wall surrounding on top of the outer bottom portion and enclosing an outer of the inner surrounding wall,
wherein each one of the soldering sections of the plurality of conductive pins is received within the central hollow portion and is attached to the inner surface; each one of the securement sections of the plurality of conductive pins extends to arch between the inner bottom portion and the inner surrounding wall; and each one of the extension sections of the plurality of conductive pins is connected to the securement section and extends outward to an outer of the outer base.

2. The double-shot injection molding formed LED lead frame structure according to claim 1, wherein the inner surface comprises ribs protruded thereon, and a front end of each one of the soldering sections of the plurality of conductive pins is formed of an end edge protruded therefrom for attaching into the ribs.

3. The double-shot injection molding formed LED lead frame structure according to claim 1, wherein the inner surrounding wall includes an inner wall surface facing toward the central hollow portion and an outer wall surface opposite from the inner wall surface, and the outer surrounding wall is closely attached to the outer wall surface.

4. The double-shot injection molding formed LED lead frame structure according to claim 3, wherein a top surface is formed at a top portion of the inner surrounding wall and between the inner wall surface and the outer wall surface, and a co-plane surface is formed on a top edge of the outer surrounding wall along the top surface of the inner surrounding wall.

5. The double-shot injection molding formed LED lead frame structure according to claim 4, wherein an indented slot is further formed between the top surface and the outer wall surface, and the outer surrounding wall is further formed of a protrusion protruding therefrom to be inserted into the slot in order to construct a single piece altogether.

6. The double-shot injection molding formed LED lead frame structure according to claim 1, wherein each one of the securement sections of the plurality of conductive pins includes an inner edge and an outer edge, and the inner and outer edges of the securement section both includes a insertion pattern for the outer base to be inserted therein.

7. The double-shot injection molding formed LED lead frame structure according to claim 1, wherein a gap is formed between the inner edge of securement section and the inner bottom portion, the gap is tapered vertically with an increased lower width thereof, and the outer bottom portion is inserted into the gap to form an attachment portion.

8. The double-shot injection molding formed LED lead frame structure according to claim 1, wherein each one of the extension sections of the plurality of conductive pins is further arched downward to form a C shape.

9. The double-shot injection molding formed LED lead frame structure according to claim 1, wherein a color of the outer base is darker than a color of the inner base.

10. The double-shot injection molding formed LED lead frame structure according to claim 1, wherein the outer base is constructed by a non-conductive material of a black color, and the inner base is constructed by a non-conductive material of a white color.
